(19) United States
(12) Patent Application Publication
(10) Pub. No.: US 2024/0014778 A1
(43) Pub. Date: Jan. 11, 2024

(54) IMPROVED SOLAR CONCENTRATOR

(71) Applicant: GREENETICA DISTRIBUTION S.R.L., Abano Terme (PD) (IT)

(72) Inventors: Antonio SICHIROLLO, Montebelluna (IT); Andrea BIASUTTI, PORDENONE (IT)

(21) Appl. No.: 18/252,242

(22) PCT Filed: Aug. 23, 2021
(86) PCT No.: PCT/IB2021/057719

§ 371 Date: May 9, 2023

(30) Foreign Application Priority Data
Nov. 13, 2020 (IT) 102020000027215

(51) Int. Cl. H02S 40/22; H02S 20/32; H02S 40/32

(52) U.S. Cl. CPC H02S 40/22; H02S 20/32; H02S 40/32

(57) ABSTRACT

Solar concentrator including support defining a main axis transversal to ground, reflecting mirror constrained to the support and defining a rotation axis transversal to the main axis around which the mirror can rotate relative to the support, and a concave shaped profile to focus solar rays towards a focal zone, a receiver to acquire the focused solar rays, controller to move, on command, the mirror around the axes relative to the support and including a processor and motor. The receiver includes acquisition strings parallel to the rotation axis, operationally connected to the processing generator and for converting the solar rays into electrical energy. The processor to detect the electrical energy quantity acquired by each string with a predetermined sampling frequency, to calculate the sum of the electrical energies and move the mirror along a spiral trajectory until identifying a mirror position at which the sum is maximum.

The present invention relates to an improved solar concentrator of the type specified in the preamble of the first claim.

In particular, the present invention relates to a solar concentrator which implements a solar tracking system configured to maximize the efficiency of the concentrator.

As known, solar concentrators or solar concentrating systems, also known by the acronym CSP (Concentrating Solar Power), allow you to convert solar energy into thermal and/or electrical energy by exploiting the reflection of sunlight obtained through reflective surfaces generally consisting of mirrors.

Such mirrors can define various shapes and sizes. Among the most used reflectors there are certainly cylindrical reflectors, parabolic reflectors and paraboloid reflectors.

The reflecting surfaces are, therefore, configured to concentrate the sun's rays on a small receiver. The concentration mode, in detail, may depend on the shape of the reflectors which can reflect the sun's rays along a linear acquisition zone or along a point-like acquisition zone.

Generally, once the rays are concentrated in the acquisition area, the solar radiation is converted into electricity and/or the heat is converted into mechanical energy by means of a heat engine, for example consisting of a steam turbine, to whose driving axis it is connected the axis of an electric generator.

In particular, the motor axis and the generator axis can be mutually connected in an integral or proportional manner, for example by means of a mechanical transmission.

Generally, the reflecting surfaces are managed by a sun tracking system designed to maximize the reception of the sun's rays and, therefore, also the accumulated energy.

The tracking systems commonly used today substantially comprise a pointing apparatus configured, by means of suitable algorithms, to process astronomical data through which to orient the reflecting surfaces.

The known art described includes some important drawbacks.

In particular, the tracking or pointing systems just described allow to optimize the pointing only in a rough way.

Therefore, it is not possible to create high-precision systems using only the common astronomical pointing systems.

Furthermore, pointing systems are mainly based on the relative position between reflective surfaces and the sun and, especially in bad weather, it may be inefficient to adopt similar systems since chasing the sun may not be the best choice in terms of energy storage.

In this situation, the technical task underlying the present invention is to devise an improved solar concentrator capable of substantially obviating at least part of the aforementioned drawbacks.

Within the scope of said technical task, it is an important object of the invention to obtain an improved solar concentrator which increases the pointing accuracy of the concentrator, thus maximizing the accumulated energy.

Another important object of the invention is to realize a solar concentrator which does not depend solely on the relative position with the sun and which allows to maximize the accumulated energy regardless of the atmospheric condition of the environment in which the concentrator is located.

The technical task and the specified aims are achieved by an improved solar concentrator as claimed in the annexed claim 1.

Preferred technical solutions are highlighted in the dependent claims.

The characteristics and advantages of the invention are clarified below by the detailed description of preferred embodiments of the invention, with reference to the accompanying figures, in which:

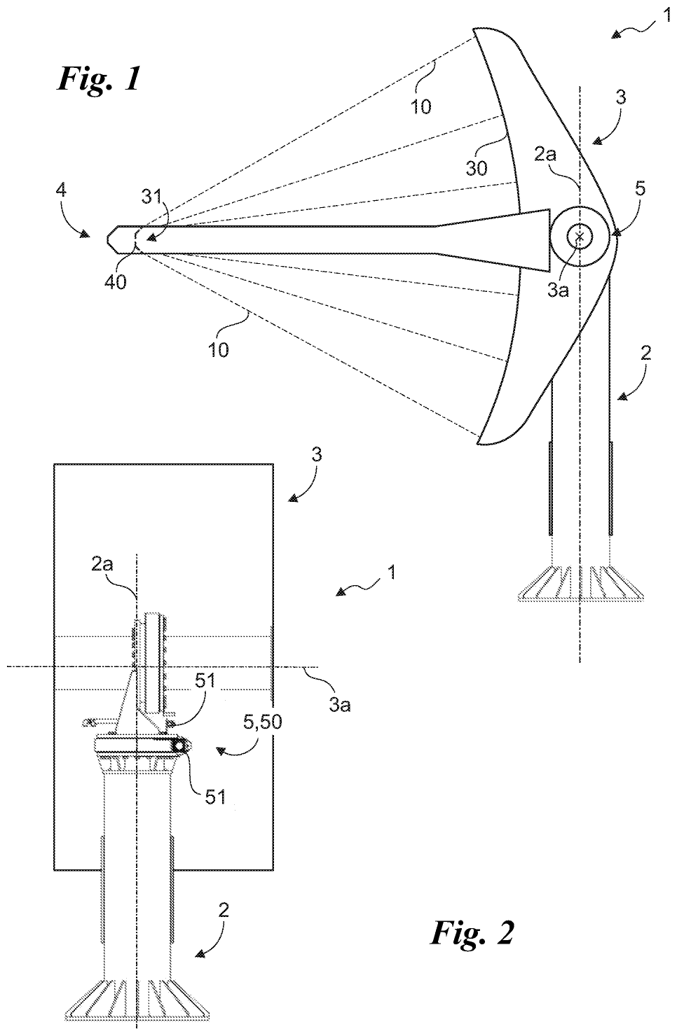

the FIG. 1 shows a side view of an improved solar concentrator according to the invention;

the FIG. 2 illustrates a rear view of part of an improved solar concentrator according to the invention; and

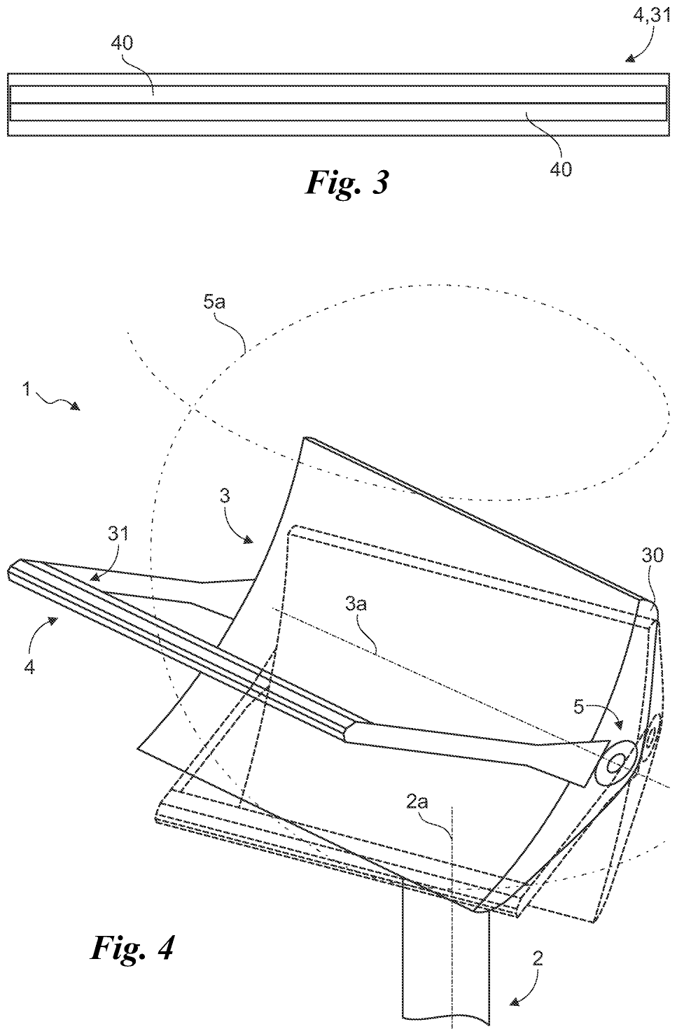

the FIG. 3 is a front view of the receiver in detail of an improved solar concentrator according to the invention; and

the FIG. 4 represents an example of the handling of an improved solar concentrator mirror according to the invention wherein the spiral trajectory is shown.

In the present document, the measurements, values, shapes and geometric references (such as perpendicularity and parallelism), when associated with words like “about” or other similar terms such as “approximately” or “substantially”, are to be considered as except for measurement errors or inaccuracies due to production and/or manufacturing errors, and, above all, except for a slight divergence from the value, measurements, shape, or geometric reference with which it is associated. For instance, these terms, if associated with a value, preferably indicate a divergence of not more than 10% of the value.

Moreover, when used, terms such as “first”, “second”, “higher”, “lower”, “main” and “secondary” do not necessarily identify an order, a priority of relationship or a relative position, but can simply be used to clearly distinguish between their different components.

Unless otherwise specified, as results in the following discussions, terms such as “treatment”, “computing”, “determination”, “calculation”, or similar, refer to the action and/or processes of a computer or similar electronic calculation device that manipulates and/or transforms data represented as physical, such as electronic quantities of registers of a computer system and/or memories in, other data similarly represented as physical quantities within computer systems, registers or other storage, transmission or information displaying devices.

The measurements and data reported in this text are to be considered, unless otherwise indicated, as performed in the International Standard Atmosphere ICAO (ISO 2533:1975).

With reference to the Figures, the improved solar concentrator according to the invention is globally indicated with the number 1.

The concentrator 1 is substantially configured to concentrate solar rays 10 in a predetermined point or zone in such a way as to acquire concentrated solar energy.

In particular, the concentrator 1 preferably comprises a support 2.

The support 2 is substantially an element that allows one or more components to be supported in elevation on a ground. Therefore, the support 2 itself is able to be placed on the ground and, preferably, constrained thereon.

Furthermore, the support 2 preferably defines a main axis 2a.

The main axis 2a is substantially the prevailing expansion axis of the support 2. Therefore, the main axis 2a is able to be transversal with respect to the ground. Even more in detail, preferably the main axis 2a is perpendicular to the ground.

The support 2 can therefore substantially be a long object extending along the main axis 2a, for example a cylindrical object such as a pole or a pylon.

The concentrator 1 also comprises at least one reflecting mirror 3.

The mirror 3 is substantially a reflecting device configured to receive solar rays 10 and reflect them on the basis of predetermined and material-dependent reflection angles.

Reflecting devices for concentrators are well known in the current state of the art. The mirror 3 is preferably constrained in a compliant way to the support 2. In particular, preferably, the mirror 3 is constrained to the support 2 in such a way as to determine at least two degrees of freedom with respect to said support 2.

The mirror 3 therefore defines a rotation axis 3a.

The rotation axis 3a is preferably transverse with respect to the main axis 2a. Furthermore, the rotation axis 3a is the axis around which the mirror 3 can rotate with respect to the support 2. Therefore, the axis of rotation 3a defines one of the degrees of freedom of the mirror 3.

Furthermore, the mirror 3 can rotate with respect to the support 2 also around the main axis 2a.

The rotations of the mirror 3 with respect to the support 2 therefore allow the concentrator 1 to vary the incidence between the mirror 3 and the solar rays 10, thus also varying the relative angles of reflection between the solar rays 10 and mirror 3. The mirror 3 additionally defines a profile 30.

The profile 30 is substantially determined by a section plane normal to the rotation axis 3a. Therefore, the profile 30 is substantially the shape of the mirror 3 incident with respect to the sun's rays as visible, for example, from a lateral point of view with respect to the mirror 3, shown in FIG. 1.

The profile 30, in particular, is substantially of concave shape. In this regard, for example, the profile 30 can be semicircular. Or, even more conveniently, the profile 30 defines a parabolic shape.

In any case, the profile 30 is configured to focus solar rays 10 towards a focal zone 31.

The focal zone 31 can define various shapes. For example, if the profile 30 is of semicircular or parabolic shape and extends with the same shape along the rotation axis 3a, the focal zone 31 can be defined by a focusing strip or band.

If, on the other hand, the mirror 3 defines, as a whole, a paraboloid shape, then the focal zone 31 can be substantially localized around a specific point.

The concentrator 1 therefore also comprises a receiver 4.

The receiver 4 is substantially configured to acquire the solar rays 10 focused by the mirror 3.

The receiver 4 is therefore arranged in correspondence with the focal zone 31. In this sense, the receiver 4 can just extend parallel to the rotation axis 3a.

The receiver 4 can, structurally, be constrained to the mirror 3 creating a bridge frame.

The receiver 4 advantageously comprises a plurality of acquisition strings 40.

The strings 40 preferably extend parallel to the rotation axis 3a.

Furthermore, they extend side by side.

The strings 40 can be of any number and, preferably, they are two in number.

Even more in detail, each string 40 comprises a plurality of photovoltaic modules.

The photovoltaic modules are therefore arranged in series parallel to the rotation axis 3a.

In addition, the photovoltaic modules are operationally connected to a multi-string photovoltaic inverter.

Basically, the strings 40 are adapted to take solar energy to generate electrical energy. In addition, the electrical energy developed in direct current is changed into alternating current by the inverter.

In general, each string 40 is configured to convert the solar energy determined by the solar rays 10 into electrical energy.

The concentrator 1 also comprises control means 5.

The control means 5 are preferably configured to move, on command, the mirror 3. In particular, the control means 5 control the movement of the mirror 3 with respect to the support 2 around the main axis 2a and around the rotation axis 3a.

In this regard, preferably, the control means 5 comprise at least one processor 50 and one or more motors 51.

The processor 50 is substantially of the electronic type and allows to acquire, process and forward signals to other components such as, for example, the motors 51 and/or the mirror 3 for their actuation.

In this sense, the processor 50 can be any electronic controller, possibly also a computer, preferably a PLC.

The motors 51 can be of any type. Preferably, the motors 51 are of the electric type. Furthermore, the motors 51 are controlled by the computer 50.

Even more in detail, the motors 51 are two in number. Preferably, each of the motors 51 is dedicated to movement around a respective axis 2a, 3a.

This means that the degrees of freedom of mirror 3 are mutually independent.

The motors 51, of course, can define a particular movement phase.

For example, each of the motors 51 can define a minimum rotation resolution, or a nominal rotation speed, equal to 1500 rpm. Of course, the speeds may vary according to the type of motors 51 used.

Advantageously, the strings 40 are operatively connected to the processor 50. Furthermore, the processor 50 is configured to carry out programmed actions. The processor 50, in fact, is configured to detect the electrical energy acquired by each string 40. The detection of the quantity of electrical energy is carried out in a continuous and sequential manner. Therefore, preferably, the processor 50 defines, during the detection phase, a predetermined sampling frequency.

For example, the minimum sampling rate can be 20 Hz, corresponding to sampling intervals of approximately 50 ms. Even more preferably, the minimum sampling frequency can be approximately equal to 50 Hz, or corresponding to sampling intervals approximately equal to 20 ms.

Of course, the sampling frequency can vary according to the type of processor 50 used.

Furthermore, the processor 50 is configured to calculate the sum of the electrical energies of the strings 40. The sum is substantially preferably the arithmetic sum of the quantities of energy detected by the different strings 40.

The processor 50 is, therefore, configured to move the mirror 3 by means of the one or more motors 51.

In particular, by virtue of the possible degrees of freedom, the motors 51 advantageously move, when operated by the computer 50, the mirror 3 along a spiral trajectory 5a.

A simple example of a spiral trajectory 5a is shown in FIG. 4.

Even more in detail, the processor 50 moves the mirror 3 until it identifies a maximum position of the mirror 3 at which the sum is maximum.

Therefore, the receiver 4 and the control means 5 realize an integrated control system of the acquired energy which pushes the mirror 3 always in the positions of maximum acquisition.

The operation of the improved solar concentrator 1 previously described in structural terms is substantially explained by the procedure described below.

The invention comprises a new method of concentrating solar rays.

The process essentially comprises the concentrator 1 as previously described.

The procedure comprises at least a detection phase, a calculation phase and a movement phase.

In the detection phase the quantity of electrical energy is acquired by each string 40 with a predetermined sampling frequency.

In the calculation phase, the sum of the electrical energies is calculated.

In the movement phase, the mirror 3 is moved by means of the one or more motors 51 along the spiral trajectory 5a until a maximum position of the mirror 3 is identified in correspondence with which the sum of the electrical energies is maximum. Preferably, the phases of detection, calculation and movement are carried out together step by step. In this way, step by step, the processor 50 continues to compare the sum values found until the maximum position or positions is determined.

Spiral trajectories 5a can, of course, be ascending and descending.

Furthermore, they can be broken and not continuous.

The process could also include an additional preparation phase.

If present, in the preparation phase the mirror 3 is preferably rotated around the main axis 2a so that the rotation axis 3a is perpendicular to the east-west direction and the mirror 3 is oriented towards the east.

In other words, in the preparation phase the mirror 3 is arranged oriented towards the direction which is supposed to be the maximum direction.

The improved solar concentrator 1 according to the invention achieves important advantages.

In fact, the concentrator 1 allows to avoid the use of particular detectors or pointers by substantially exploiting the simple detection of the quantities of electrical energy acquired by the various strings 40.

Furthermore, the concentrator 1 is, in the face of a less complex structure, very precise since it implements a control method that is not astronomical.

In particular, the concentrator 1 makes it possible to efficiently point the mirror 3 towards the maximum position regardless of the position of the sun but solely depending on the greater energy detected.

The invention is susceptible of variants falling within the scope of the inventive concept defined by the claims.

In this context, all the details can be replaced by equivalent elements and the materials, shapes and dimensions can be any.

1. An improved solar concentrator comprising:
a support defining a main axis transversal to a ground,
at least one reflecting mirror constrained in a compliant way to said support and defining:
a rotation axis transversal to said main axis around which said mirror can rotate with respect to said support, and
a profile determined by a plane of section normal to said axis of rotation of concave shape and configured to focus solar rays towards a focal zone,
a receiver configured to acquire said solar rays focused by said mirror arranged at said focal zone, and
control means configured to move, on command, said mirror around said main axis and around said rotation axis with respect to said support and comprising at least one processor and one or more motors controlled by said processor,
wherein said receiver comprises a plurality of acquisition strings extending side by side parallel to said rotation axis, operatively connected to said processor and configured for convert the solar energy determined by said solar rays into electrical energy, and
wherein said processor is configured to detect the quantity of said electrical energy acquired by each said string with a predetermined sampling frequency, to calculate the sum of said electrical energies and to move said mirror by means of said one or more motors along a spiral trajectory until a maximum position of said mirror is identified at which this sum is maximum.

2. The concentrator according to claim 1, wherein said profile defines a parabolic shape.

3. The concentrator according to claim 1, wherein said processor is a PLC and said motors are two in number, each of which dedicated to the movement around a respective said axis.

4. The concentrator according to claim 1, wherein each of said motors defines a minimum rotational resolution equal to 1500 rpm.

5. The concentrator according to claim 1, wherein said strings each comprise a plurality of photovoltaic modules arranged in series parallel to said axis of rotation and operatively connected to a multi-string PV inverter.

6. The concentrator according to claim 1, wherein said strings are two in number.

7. The concentrator according to claim 1, wherein said minimum sampling frequency is equal to 20 Hz.

8. A process of concentrating solar rays comprising a concentrator according to claim 1, and characterized by comprising at least:
detecting the quantity of said electrical energy acquired by each said string with a sampling frequency predetermined,
calculate the sum of said electrical energies, and
moving said mirror by means of said one or more motors along a spiral trajectory until a maximum position of said mirror at which this sum is maximum.

9. The process according to claim 8, comprising a configuration phase wherein said mirror is rotated around said main axis in such a way that said rotation axis is perpendicular to the east-west direction and said mirror faces east.

10. The process according to claim 8, wherein said detection, calculation and movement phases are carried out together step by step.

11. The process according to claim 9, wherein said detection, calculation and movement phases are carried out together step by step.

12. The concentrator according to claim 2, wherein said processor is a PLC and said motors are two in number, each of which dedicated to the movement around a respective said axis.

13. The concentrator according to claim 12, wherein each of said motors defines a minimum rotational resolution equal to 1500 rpm.

14. The concentrator according to claim 13, wherein said strings each comprise a plurality of photovoltaic modules arranged in series parallel to said axis of rotation and operatively connected to a multi-string PV inverter.

15. The concentrator according to claim 14, wherein said strings are two in number.

16. The concentrator according to claim 15, wherein said minimum sampling frequency is equal to 20 Hz.
